(19) United States
(12) Patent Application Publication
(10) Pub. No.: US 2012/0218704 A1
(43) Pub. Date: Aug. 30, 2012

(54) DISK DRIVE ASSEMBLY

(75) Inventors: YUN-LUNG CHEN, Tu-Cheng (TW); LIANG-CHIN WANG, Tu-Cheng (TW); JIAN HU, Wuhan City (CN); YU-MING XIAO, Wuhan City (CN); ZAN LI, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/397,787

(22) Filed: Feb. 16, 2012

(30) Foreign Application Priority Data
Feb. 24, 2011 (CN) 201110044485.0

(51) Int. Cl. G06F 1/16; H05K 7/00

(52) U.S. Cl. 361/679.33; 248/309.1

(57) ABSTRACT

A disk drive assembly includes a disk drive, a drive bracket, and a securing member. The disk drive includes a sidewall with a securing hole. The drive bracket receives the disk drive therein. The drive bracket includes a first side panel. The first side panel includes a side panel body substantially parallel to the sidewall and a securing tab extending from the side panel body. A through hole is defined in the side panel body. A securing slot is defined in the securing tab. The securing member includes a member panel, a pivoting portion, and a securing portion. The pivoting portion is pivotably mounted to the first side panel. The member panel includes a positioning tab passing through the through hole to be inserted in the securing hole. The securing portion engages with the securing slot to prevent the securing member from moving away from the first side panel.

### BACKGROUND

1. Technical Field

The disclosure generally relates to a disk drive assembly.

2. Description of Related Art

Many disk drives may be secured in a drive bracket. The drive bracket defines a number of through holes, and each disk drive defines a number of fixing holes. In assembly, the disk drive is inserted in the drive bracket, and the fixing holes are aligned with the through holes. A number of screws may be secured into the fixing holes through the through holes to secure the disk drive to the drive bracket. It may be inconvenient to assemble or disassembly the disk drive to the drive bracket.

Thus, there is room for improvement within the art.

### BRIEF DESCRIPTION OF THE DRAWINGS

FIG. 1 is an exploded, isometric view of an embodiment of a disk drive assembly.

FIG. 2 is an isometric view of a disk drive of FIG. 1.

FIG. 3 is an isometric view of a drive bracket of FIG. 1.

FIG. 4 is an assembled view of the disk drive assembly of FIG. 1.

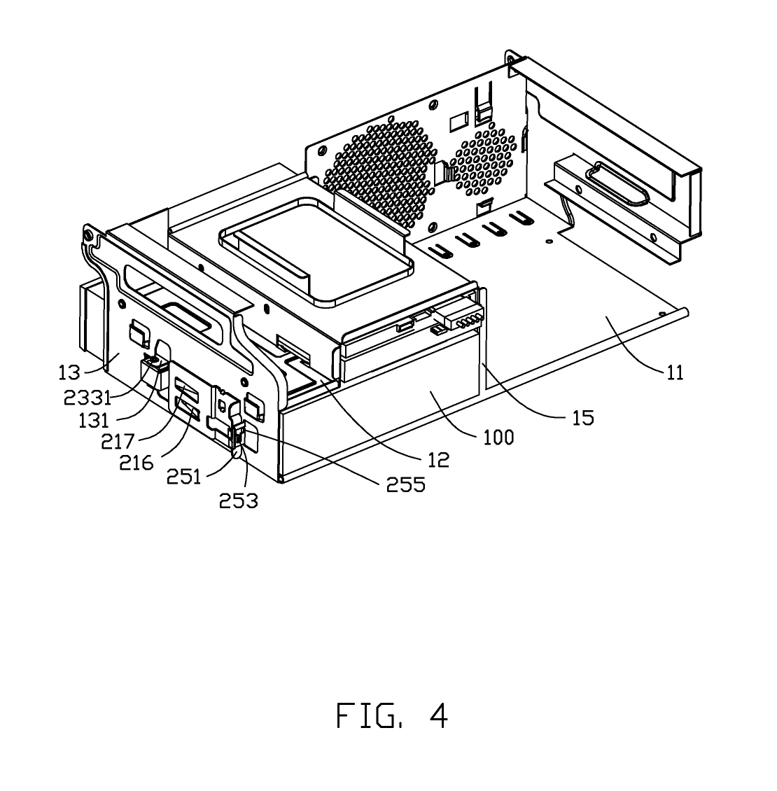

FIG. 5 is an enlarged and partial view of FIG. 4.

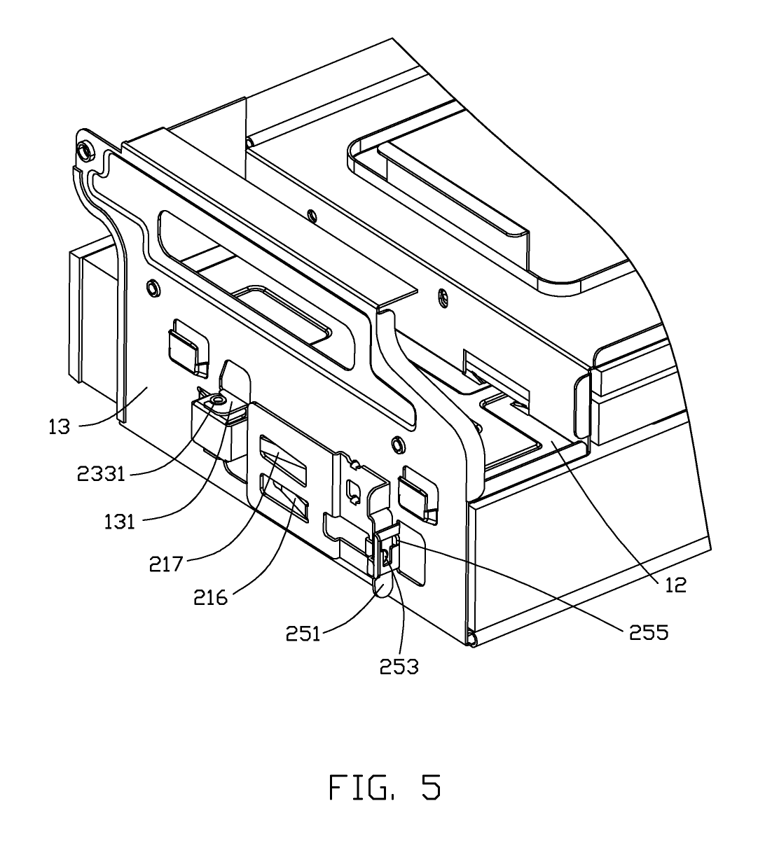

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

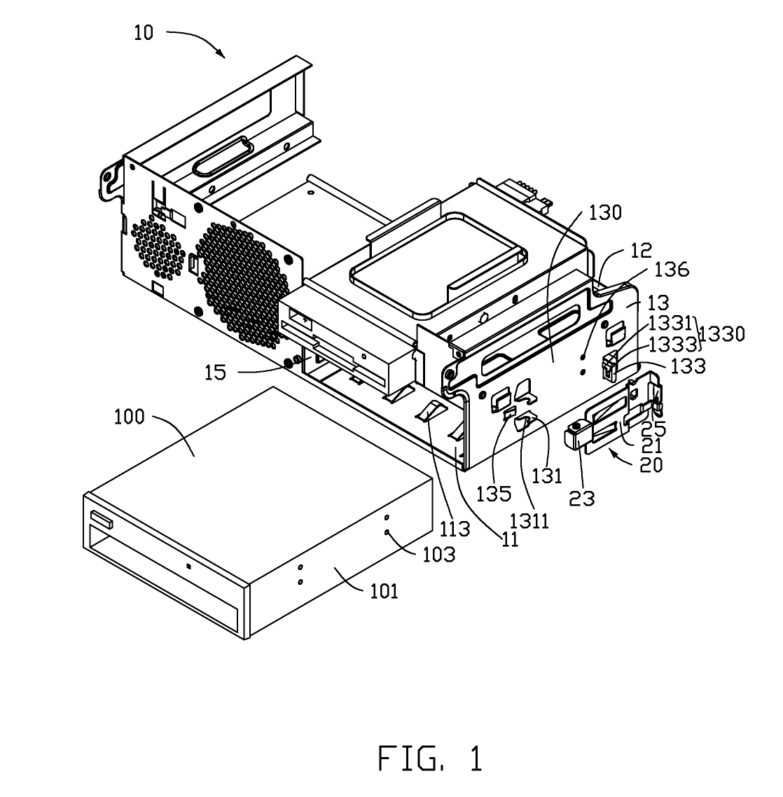

Referring to FIG. 1, a disk drive assembly in accordance with an embodiment includes a disk drive 100 and a mounting apparatus. The mounting apparatus includes a drive bracket 10 and a securing member 20.

The disk drive 100 includes two sidewalls 101 parallel to each other. Each of the two sidewalls 101 defines two securing holes 103.

The drive bracket 10 includes a bottom panel 11, a top panel 12 parallel to the bottom panel 11, a first side panel 13 substantially perpendicularly extending from the bottom panel 11, and a second side panel 15 substantially perpendicularly extending from the bottom panel 11. The first side panel 13 is parallel to the second side panel 15. The bottom panel 11 includes a plurality of contacting tab 113. The first side panel 13 includes a side panel body 130 parallel to each of the two sidewalls 101 and two mounting tabs 131, a securing tab 133 and a stopper tab 135 extending from the side panel body 130. The two mounting tabs 131 are substantially parallel to each other. Each of the two mounting tabs 131 defines a cutout 1311. The securing tab 133 defines a securing slot 1330. The securing slot 1330 is L-shaped. The securing slot 1330 includes a first part 1331 and a second part 1333 communicating with the first part 1331. The extending direction of the first part 1331 is substantially perpendicular to the extending direction of the second part 1333. The extending direction of the first part 1331 is substantially perpendicular to the side panel body 130, and the extending direction of the second part 1333 is substantially parallel to the side panel body 130.

The stopper tab 135 extends slantingly and toward the two mounting tabs 131. The side panel body 130 defines two through holes 136 corresponding to the two securing holes 103.

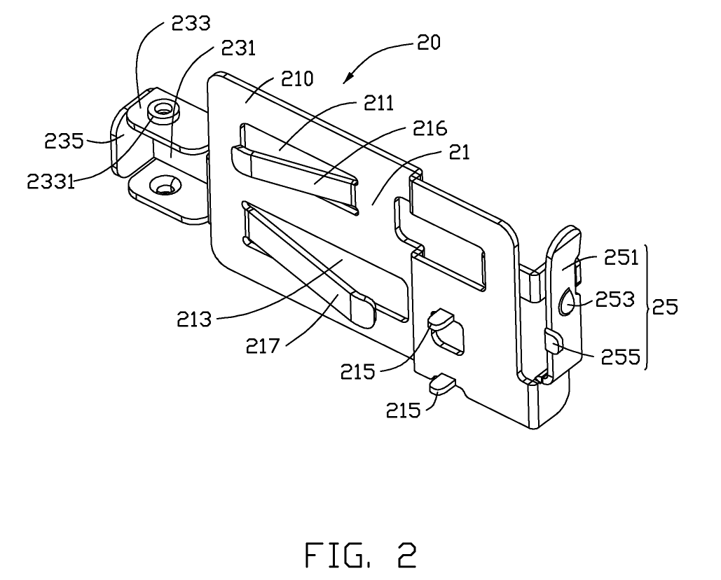

Referring to FIG. 2, a securing member 20 includes a member panel 21, a pivoting portion 23 extending from the member panel 21, and a securing portion 25 extending from the member panel 21. The member panel 21 includes a panel body 210. The panel body 210 defines a first opening 211 and a second opening 213. The member panel 21 further includes a first resilient tab 216 extending slantingly from an edge of the first opening 211 in a first direction and a second resilient tab 217 extending slantingly from an edge of the second opening 213 in a second direction substantially opposite to the first direction. The member panel 21 further includes two positioning tabs 215 extending from the panel body 210 corresponding to the through holes 136. The pivoting portion 23 includes a mounting plate 231 and two pivoting tabs 233 extending from opposite sides of the mounting plate 231. Each of the two pivoting tabs 233 includes a pivoting protrusion 2331 corresponding to the cutout 1311. The pivoting portion 23 further includes a resisting tab 235 perpendicularly extends from the mounting plate 231. The securing portion 25 includes a resilient arm 251, a securing protrusion 253 extending from the resilient arm 251, and a resisting protrusion 255 extending from the resilient arm 251.

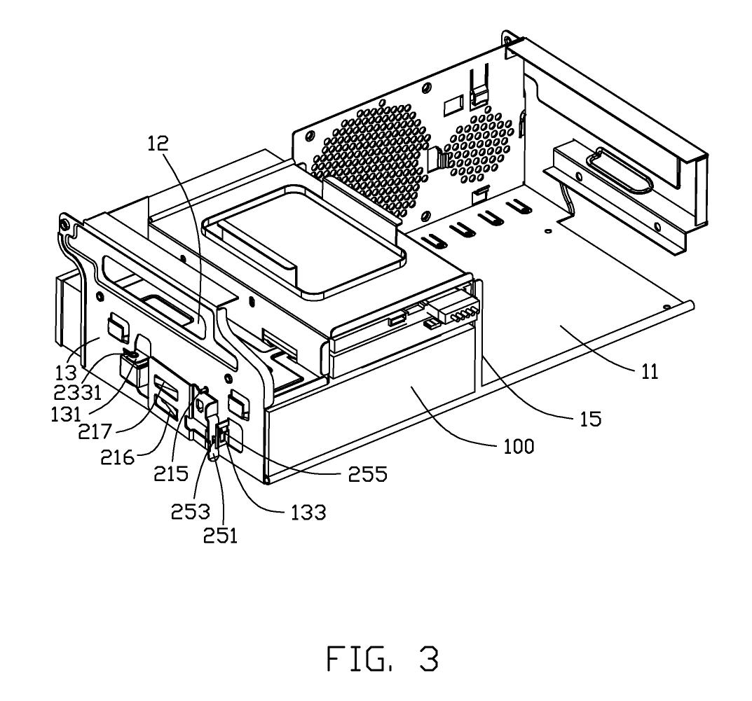

Referring to FIG. 3, in assembly, the pivoting portion 23 of the securing member 20 contacts the first side panel 13 and moves along a first direction substantially parallel to the side panel body 130 to press the stopper tab 135. The stopper tab 135 is deformed to move towards the side panel body 130. The pivoting protrusion 2331 of the pivoting portion 23 moves into the cutout 1311 to be rotatbly mounted in the cutout 1311. At this time, the stopper tab 135 releases to prevent the pivoting portion 23 from moving along a second direction opposite to the first direction. The resisting protrusion 255 is disposed in the first part 1331 of the securing slot 1330. The two positioning tabs 215 are aligned with the two through holes 136. The disk drive 100 is aligned with the drive bracket 10. The disk drive 100 is moved into the drive bracket 10 to enable the securing holes 103 to be aligned with the through holes 136. At this time, the disk drive 100 is located between the bottom panel 11 and the top panel 12, and also located between the first side panel 13 and the second side panel 15. The securing member 20 rotates towards to the first side panel 13. The securing protrusion 253 resists the securing tab 133 to enable the resilient arm 251 to be deformed. The securing protrusion 253 engages with the second part 1333 of the securing slot 1330 when the securing protrusion 253 is aligned with the second part 1333 of the securing slot 1330.

At this time, the two positioning tabs 215 pass through the through holes 136 to be inserted in the securing holes 103 of the disk drive 100, thereby securing the disk drive 100 in the drive bracket 10.

In disassembly, the resilient arm 251 is pressed to drive the securing protrusion 253 to disengage from the second part 1333 of the securing slot 1330. The securing member 20 is pulled to rotate away from the first side panel 13 driving the two positioning tabs 215 to move out of the securing holes 103 of the disk drive 100. The disk drive 100 can be easily pulled out of the drive bracket 10.

It is to be understood, however, that even though numerous characteristics and advantages have been set forth in the foregoing description of embodiments, together with details of the structures and functions of the embodiments, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A disk drive assembly comprising:
a disk drive, the disk drive comprising a sidewall, a securing hole defined in the sidewall;
a drive bracket, the drive bracket receiving the disk drive therein, the drive bracket comprising a first side panel, the first side panel comprising a side panel body substantially parallel to the sidewall and a securing tab extending from the side panel body; a through hole defined in the side panel body; and a securing slot defined in the securing tab; and
a securing member, the securing member comprising a member panel, a pivoting portion extending from the member panel, and a securing portion extending from the member panel; the pivoting portion pivotably mounted to the first side panel; the member panel comprising a positioning tab passing through the through hole to be inserted in the securing hole; and the securing portion engaging with the securing slot to prevent the securing member from moving away from the first side panel.

2. The disk drive assembly of claim 1, wherein the securing portion comprises a resilient arm extending from the member panel, a securing protrusion extending from the resilient arm, and a resisting protrusion extending from the resilient arm; the securing protrusion engages with the securing slot; the resisting protrusion located in the securing slot; and the resilient arm is configured to be deformed to drive the securing protrusion to disengage from the securing slot when the resilient arm is pressed.

3. The disk drive assembly of claim 2, wherein the securing slot is L-shaped; the securing slot defines a first part and a second part communicating with the first part; an extending direction of the first part is substantially perpendicular to an extending direction of the second part; the resisting protrusion is located in the first part; and the securing protrusion engages the second part.

4. The disk drive assembly of claim 3, wherein the extending direction of the first part is substantially perpendicular to the side panel body, and the extending direction of the second part is substantially parallel to the side panel body.

5. The disk drive assembly of claim 1, wherein the pivoting portion comprises a mounting plate extending from member panel and two pivoting tabs extending from opposite sides of the mounting plate; the first side panel further comprises two mounting tabs extending from the side panel body and a stopper tab extending slantingly from the side panel body; each of the two mounting tabs defines a cutout; the pivoting portion is configured to press the stopper tab to move close to the side panel body to move along a first direction to the two mounting tabs, thereby enabling each of the two pivoting tabs to be received in the cutout; and the stopper tab is configured to release to prevent the pivoting portion from moving along a second direction opposite to the first direction when each of the two pivoting tabs is received in the cutout.

6. The disk drive assembly of claim 1, wherein the member panel comprises a panel body and a first resilient tab extending inclining from the panel body in a first direction, the first resilient tab resisting the first side panel.

7. The disk drive assembly of claim 6, wherein the member panel comprises a second resilient tab extending slantingly from the panel body in a second direction substantially opposite to the first direction.

8. The disk drive assembly of claim 1, wherein the drive bracket further comprises a second side panel substantially parallel to the first side panel, and the disk drive is located between the first side panel and the second side panel.

9. A mounting apparatus for mounting a disk drive, comprising:
a drive bracket, the drive bracket receiving the disk drive therein, the drive bracket comprising a bottom panel, a first side panel, and a second side panel extending from the bottom panel, the first side panel substantially parallel to the second side panel; the first side panel and the second side panel configured to mount the disk drive therebetween, the first side panel comprising a side panel body, two mounting tabs extending from the side panel body and a stopper tab extending slantingly from the side panel body; each of the two mounting tabs defines a cutout; and
a securing member, the securing member comprising a member panel, a pivoting portion extending from the member panel, and a securing portion extending from the member panel; the pivoting portion comprising two pivoting tabs; the pivoting portion configured to move along a first direction parallel to the side panel body to be received in each of the cutout to enable the pivoting portion pivotably mounted to the first side panel by pressing the stopper tab to move close to the side panel body; the stopper tab configured to release to prevent the pivoting portion from moving along a second direction opposite to the first direction when each of the two pivoting tabs is received in the cutout; and the member panel comprising a positioning tab configured to be inserted in a securing hole of the disk drive to prevent the disk drive from moving along a third direction substantially parallel to the side panel body.

10. The mounting apparatus of claim 9, wherein the first side panel further comprises a securing tab extending from the side panel body; a securing slot is defined in the securing tab; the securing portion comprises a resilient arm extending from the member panel, a securing protrusion extending from the resilient arm, and a resisting protrusion extending from the resilient arm; the securing protrusion engages with the securing slot; the resisting protrusion located in the securing slot; and the resilient arm is configured to be deformed to drive the securing protrusion to disengage from the securing slot when the resilient arm is pressed.

11. The mounting apparatus of claim 10, wherein the securing slot is L-shaped; the securing slot defines a first part and a second part communicating with the first part; an extending direction of the first part is substantially perpendicular to an extending direction of the second part; the resisting protrusion is located in the first part; and the securing protrusion engages the second part.

12. The mounting apparatus of claim 11, wherein the extending direction of the first part is substantially perpendicular to the side panel body, and the extending direction of the second part is substantially parallel to the side panel body.

13. The mounting apparatus of claim 9, wherein the member panel comprise a panel body and a first resilient tab extending inclining from the panel body in a first direction, the first resilient tab resisting the first side panel.

14. The mounting apparatus of claim 13, wherein the member panel comprise a second resilient tab extending slantingly from the panel body in a second direction substantially opposite to the first direction.

15. The mounting apparatus of claim 9, wherein a through hole is defined in the side panel body; and the positioning tab is configured to pass through the through hole to be inserted in the securing hole of the disk drive.
